(19) United States
(12) Patent Application Publication
(10) Pub. No.: US 2025/0248269 A1
(43) Pub. Date: Jul. 31, 2025

(54) DISPLAY APPARATUS

(71) Applicant: LG Display Co., Ltd., Seoul (KR)

(72) Inventor: Heeseok NOH, Paju-si (KR)

(21) Appl. No.: 18/795,956

(22) Filed: Aug. 6, 2024

(30) Foreign Application Priority Data
Jan. 26, 2024 (KR) 10-2024-0012220

(51) Int. Cl. H10K 59/80; H10K 59/40; H10K 102/00

(52) U.S. Cl. CPC H10K 59/8722; H10K 59/40; H10K 2102/311

(57) ABSTRACT

A display apparatus may include a display panel including a first region, a second region overlapping the first region, and a third region between the first region and the second region, a printed circuit board disposed at the first region and the second region, and a controller disposed on a printed circuit board. The display panel may be bent in the third region, and the printed circuit board may include a first hole.

### CROSS-REFERENCE TO RELATED APPLICATION

The present application claims priority to Korea Patent Application No. 10-2024-0012220, filed Jan. 26, 2024, the entire contents of which is incorporated herein for all purposes by this reference.

### BACKGROUND

### Technical Field

The present disclosure relates to a display apparatus.

### Description of the Related Art

As the information society develops, various demands for display apparatuses for displaying images are increasing, and various types of display apparatuses such as liquid crystal display (LCD) apparatuses and organic light emitting diode (OLED) display apparatuses are utilized.

Among the display apparatuses, there is an advantage in that the OLED display apparatus as the self-luminous type has a wider viewing angle, a higher contrast ratio, is lighter, thinner, and has lower a power consumption than the LCD because it does not require a separate backlight. In addition, there is an advantage in that the OLED display apparatus may drive at a low voltage, have a fast response time, and especially have inexpensive manufacturing cost.

### BRIEF SUMMARY

The present disclosure is directed to providing a display apparatus with enhanced adhesive force (or attaching force) between a printed circuit board and a plate layer of a display panel.

The present disclosure is directed to providing a display apparatus in which the occurrence of lifting in an area on a printed circuit board on which a controller is disposed and an area near a printed circuit board on which the controller is disposed can be minimized.

A display apparatus according to an embodiment of the present disclosure may include a display panel including a first region, a second region overlapping the first region, and a third region between the first region and the second region, a printed circuit board disposed at the first region and the second region, and a controller disposed on the printed circuit board. The display panel may be bent in the third region. The printed circuit board may include a first hole.

A display apparatus according to various embodiments of the present disclosure may include a display panel including a first region, a second region overlapping the first region, and a third region between the first region and the second region, a printed circuit board disposed in the first region and the second region, and a controller disposed on the printed circuit board. The display panel may be bent in the third region. The printed circuit board may include a first hole. The controller may include a first controller and a second controller spaced apart from the first controller.

A display apparatus according to another embodiment of the present disclosure may include a display panel including a first region, a second region overlapping the first region, and a third region between the first region and the second region, a printed circuit board disposed at the first region and the second region, and a first coupling layer in a portion of the first region and being under the printed circuit board. The printed circuit board may include a first hole. The first coupling layer may include a second hole. The first hole and the second hole may overlap each other. The first hole and the second hole may have different sizes to define a step.

A display apparatus according to various exemplary embodiments of the present disclosure may include a display panel, a printed circuit board disposed over the display panel, and a controller disposed on the printed circuit board. The printed circuit board may include a first hole. The first hole may overlap the controller.

According to embodiments of the present disclosure, the display panel may include the bending area, and the display panel may be bent in the bending area. Therefore, it is possible to reduce the bezel area of the display panel.

According to embodiments of the present disclosure, the printed circuit board may be attached to the plate layer through the coupling layer. Therefore, it is possible to minimize the movement of the printed circuit board. Therefore, it is possible to minimize the physical interference between the printed circuit board and set components

According to embodiments of the present disclosure, it is possible to minimize the movement of the printed circuit board, thereby minimizing physical interference between the printed circuit board and the set components, reinforcing the durability of the display apparatus, and increasing the lifetime of the display apparatus.

According to embodiments of the present disclosure, in the suction operation, it is possible to remove the air bubbles remaining inside the first coupling layer, at the interface between the first coupling layer and the printed circuit board, or the interface between the first coupling layer and the plate layer. Therefore, it is possible to minimize the lifting of the printed circuit board.

According to embodiments of the present disclosure, since the printed circuit board including the hole is configured, it is possible to increase the adhesive force (or attaching force) between the plate layers in the area in which the controller of the printed circuit board is disposed in the suction operation.

According to the embodiments of the present specification, in the suction operation through the hole in the printed circuit board and the coupling layer, the air bubbles sucked through the suction device may form a vortex due to the step, thereby increasing the suction force of the suction device. Therefore, it is possible to further increase the adhesive force (or attaching force) with the plate layer MP in the area in which the controller of the printed circuit board is disposed in the suction operation.

It is to be understood that both the foregoing description and the following detailed description are exemplary and explanatory and are intended to provide further explanation of the inventive concepts as claimed.

### BRIEF DESCRIPTION OF THE SEVERAL VIEWS OF THE DRAWINGS

The accompanying drawings, which are included to provide a further understanding of the disclosure, and incorporated in and constitute a part of this disclosure, illustrate example embodiments of the disclosure and together with the description serve to explain principles of the disclosure.

FIG. 1 is a configuration diagram of a display apparatus according to an embodiment of the present disclosure.

FIG. 2 is a plan view showing a display panel and a printed circuit board of the display apparatus of FIG. 1 according to an embodiment of the present disclosure.

FIG. 3 is a plan view showing a touch panel and the printed circuit board of the display apparatus of FIG. 1 according to an embodiment of the present disclosure.

FIG. 4 is an enlarged plan view of area Q1 in FIG. 3 according to an embodiment of the present disclosure.

FIG. 5 is a cross-sectional view showing a bent state of the display apparatus according to an embodiment of the present disclosure.

FIG. 6 is a cross-sectional view of a display panel of FIG. 5.

FIG. 7 is a rear view of the display apparatus of FIG. 5 according to an embodiment of the present disclosure.

FIGS. 8 to 15 are views showing a method of manufacturing the display apparatus according to an embodiment of the present disclosure.

FIG. 16 is a rear view of a display apparatus according to another embodiment of the present disclosure.

FIG. 17 is a cross-sectional view along line C-C′ in FIG. 16 according to another embodiment of the present disclosure.

FIG. 18 is a cross-sectional view along line D-D′ in FIG. 16 according to another embodiment of the present disclosure.

FIG. 19 is a cross-sectional view showing a suction process of the display apparatus according to another embodiment of the present disclosure.

FIG. 20 is a rear view of a display apparatus according to another embodiment of the present disclosure.

FIG. 21 is a cross-sectional view along line E-E′ in FIG. 20 according to another embodiment of the present disclosure.

FIG. 22 is a cross-sectional view along line F-F′ in FIG. 20 according to another embodiment of the present disclosure.

FIG. 23 is a cross-sectional view showing a suction process of the display apparatus according to another embodiment of the present disclosure.

FIG. 24 is a rear view of the display apparatus according to another embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction of thereof may be exaggerated for clarity, illustration, and/or convenience.

### DETAILED DESCRIPTION

Reference is now made in detail to aspects of the present disclosure, examples of which may be illustrated in the accompanying drawings. In the following description, when a detailed description of well-known methods, functions, structures or configurations may unnecessarily obscure aspects of the present disclosure, a detailed description of such known functions or configurations may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

When the position relation between two parts is described using the terms such as “on”, “above”, “over”, “below”, “under”, “beside”, “beneath”, “near”, “close to,” “adjacent to”, “on a side of”, “next”, one or more parts may be positioned between the two parts unless the terms are used with the term “immediately” or “directly”.

Advantages and features of the present disclosure, and implementation methods thereof, are clarified through the aspects described with reference to the accompanying drawings. The present disclosure may, however, be embodied in different forms and should not be construed as limited to the example aspects set forth herein. Rather, these example aspects are examples and are provided so that this disclosure may be thorough and complete to assist those skilled in the art to understand the inventive concepts without limiting the protected scope of the present disclosure.

For the expression that an element (e.g., layer, film, region, component, section, or the like) is described as “connected,” “coupled,” “attached,” “adhered,” or the like to another element, the element may not only be directly connected, coupled, attached, adhered, or the like to another element, but also be indirectly connected, coupled, attached, adhered, or the like to another element with one or more intervening elements disposed or interposed between the elements, unless otherwise specified.

It is understood that, although the terms “first,” “second,” or the like may be used herein to describe various elements (e.g., layers, films, regions, components, sections, or the like), these elements should not be limited by these terms, for example, to any particular order, precedence, or number of elements. These terms are used only to distinguish one element from another. For example, a first element could be termed a second element, and, similarly, a second element could be termed a first element, without departing from the scope of the present disclosure Furthermore, the first element, the second element, and the like may be arbitrarily named according to the convenience of those skilled in the art without departing from the scope of the present disclosure. For clarity, the functions or structures of these elements (e.g., the first element, the second element and the like) are not limited by ordinal numbers or the names in front of the elements. Further, a first element may include one or more first elements. Similarly, a second element or the like may include one or more second elements or the like.

Spatially relative terms, such as “below,” “beneath,” “lower,” “on,” “above,” “upper” and the like, may be used to describe a correlation between various elements (e.g., layers, films, regions, components, sections, or the like) as shown in the drawings. The spatially relative terms are to be understood as terms including different orientations of the elements in use or in operation in addition to the orientation depicted in the drawings. For example, if the elements shown in the drawings are turned over, elements described as “below” or “beneath” other elements would be oriented “above” other elements. Thus, the term “below,” which is an example term, may include all directions of “above” and “below.” Likewise, an exemplary term “above” or “on” may include both directions of “above” and “below.” Where a term like “comprise,” “have,” “include,” “contain,” “constitute,” “made of,” “formed of,” or the like is used with respect to one or more elements, one or more other elements may be added unless a term such as “only” or the like is used. The terms used in the present disclosure are merely used in order to describe example aspects, and are not intended to limit the scope of the present disclosure. The terms of a singular form may include plural forms unless the context clearly indicates otherwise.

In describing temporal relationship, terms such as “after,” “subsequent to,” “following,” “next,” “before,” and the like may include cases where any two events are not consecutive, unless the term such as “immediately” “just” or “directly” is explicitly used.

When an element or layer is disposed “on” another element or layer, another layer or another element may be interposed directly on the other element or therebetween.

It should be understood that the term “at least one” includes all combinations related with any one item. For example, “at least one among a first element, a second element and a third element” may include all combinations of two or more elements selected from the first, second and third elements as well as each element of the first, second and third elements.

A term “apparatus” used herein may refer to a display apparatus including a display panel and a driver for driving the display panel. Examples of the display apparatus may include a light emitting element, and the like. In addition, examples of the apparatus may include a notebook computer, a television, a computer monitor, an automotive device, a wearable device, and an automotive equipment device, and a set electronic device (or apparatus) or a set device (or apparatus), for example, a mobile electronic device such as a smartphone or an electronic pad, which are complete products or final products respectively including light emitting element and the like, but embodiments of the present disclosure are not limited thereto.

Features of various aspects of the present disclosure may be partially or entirely coupled to or combined with each other, may be technically associated with each other, and may be operated, linked, or driven together in various ways. Aspects of the present disclosure may be implemented or carried out independently from each other, or may be implemented or carried out together in a co-dependent or related relationship. In one or more aspects, the components of each apparatus according to various aspects of the present disclosure may be operatively coupled and configured.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein.

In the following description, various example aspects of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, aspects of the present disclosure are not limited to a scale, dimension, size, and thickness illustrated in the drawings.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Components are interpreted to include an ordinary error range even if not expressly stated.

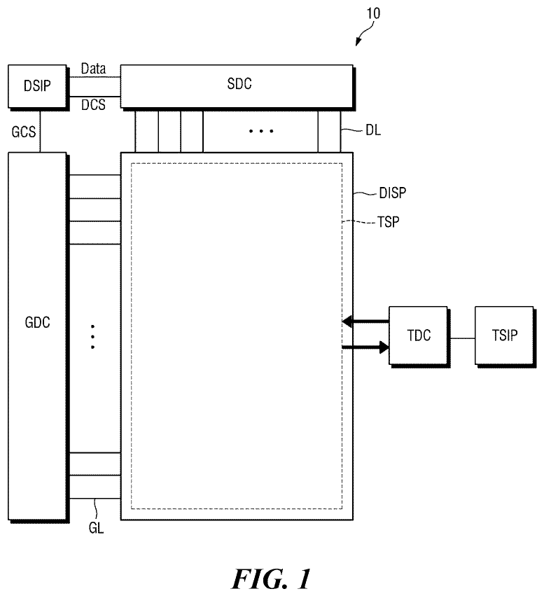

FIG. 1 is a configuration diagram of a display apparatus according to an embodiment of the present disclosure.

A display apparatus 10 according to an embodiment of the present disclosure may perform an image display function and a touch detection function (touch input function).

Referring to FIG. 1, the display apparatus 10 according to an embodiment of the present disclosure may include a display panel DISP, a source driving circuit SDC, a gate driving circuit GDC, a display controller DSIP, etc. The embodiments of the present disclosure are not limited thereto. Meanwhile, all the components of each display apparatus according to all embodiments of the present disclosure are operatively coupled and configured.

The display panel DISP may have a plurality of data lines DL and a plurality of gate lines GL. The display panel DISP may include a plurality of pixels. A plurality of pixels may display an image. The plurality of pixels may be arranged by being defined by the plurality of data lines DL and/or the plurality of gate lines GL.

A source driving circuit SDC may drive the plurality of data lines DL. A gate driving circuit GDC may drive the plurality of gate lines GL.

The display controller DSIP may control the source driving circuit SDC and the gate driving circuit GDC. The display controller DSIP may control the source driving circuit SDC and the gate driving circuit GDC by supplying various driving control signals DCS and GCS to the source driving circuit SDC and the gate driving circuit GDC.

The display controller DSIP may start scanning according to the timing implemented in each frame, convert externally input image data into a data signal format used in the data driving circuit SDC, output the converted image data Data, and control data driving at an appropriate time according to the scanning.

The display controller DSIP may receive various timing signals including, for example, a vertical synchronization signal, a horizontal synchronization signal, an input data enable signal, a clock signal, etc., to an external device (e.g., a host system) together with the input image data.

The display controller DSIP may not only convert the input image data input from the outside to suit the data signal format used in the source driving circuit SDC and output the converted image data, but also, to control the source driving circuit SDC and the gate driving circuit GDC, receive timing signals such as a vertical synchronization signal, a horizontal synchronization signal, an input data enable signal, or a clock signal, and generate and output various driving control signals DCS and GCS to the source driving circuit SDC and the gate driving circuit GDC.

The source driving circuit SDC may drive the plurality of data lines DL by receiving the image data Data from the display controller DSIP and supplying the data voltage to the plurality of data lines DL. The source driving circuit SDC may be a data driving circuit, but embodiments of the present disclosure are not limited thereto.

The source driving circuit SDC may be implemented by including at least one source driver integrated circuit (SDIC), but embodiments of the present disclosure are not limited thereto.

The gate driving circuit GDC may drive the plurality of gate lines GL by supplying a scan signal to the plurality of gate lines GL. The gate driving circuit GDC may be a scan driving circuit, but embodiments of the present disclosure are not limited thereto.

The gate driving circuit GDC may be implemented by including at least one gate driver integrated circuit (GDIC), but embodiments of the present disclosure are not limited thereto.

Meanwhile, the apparatus may further include a timing controller that may control the source driving circuit SDC and the gate driving circuit GDC. For example, the timing controller may realign digital video data, which are inputted from the outside, to fit the resolution of the display panel PN and supply the video data to the source driving circuit SDC. The timing controller may generate the gate control signal and the data control signal based on timing signals synchronized with the input image signal, such as a dot clock signal, a data enable signal, and horizontal/vertical synchronization signals. Here, the horizontal synchronization signal is a signal representing a time taken to display one horizontal line of a screen and the vertical synchronization signal is a signal representing a time taken to display a screen of one frame. The data enable signal may correspond to a signal indicating a period for which a data voltage is supplied to the pixel. The timing controller may control operation timings of the gate driving circuit GDC and the source driving circuit SDC by supplying the gate control signal to the gate driving circuit GDC and supplying the data control signal to the source driving circuit SDC.

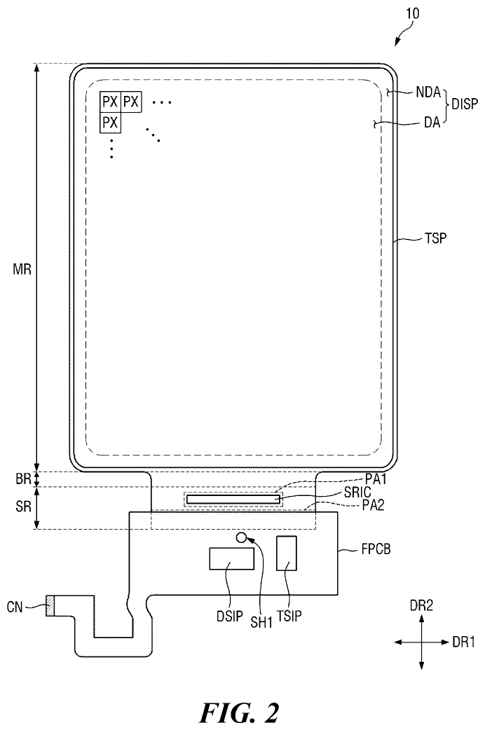

Referring to FIG. 1, the display apparatus 10 according to an embodiment of the present disclosure may include a touch panel TSP, a touch driving circuit TDC, a touch controller TSIP, etc., to provide the touch detection function. The touch panel TSP may be configured on the display panel DISP, but embodiments of the present disclosure are not limited thereto. The source driving circuit SDC and the touch driving circuit TDC may be integrated and included in an integrated IC SRIC (see FIG. 2), but embodiments of the present disclosure are not limited thereto.

FIG. 2 is a plan view showing a display panel and a printed circuit board of the display apparatus according to FIG. 1.

Referring to FIGS. 1 and 2, the display panel DISP may include a display area DA including a plurality of pixels PX and a non-display area NDA near the display area DA. The non-display area NDA is configured to be in the vicinity of the display area DA, partially or fully surround the display area DA.

The display area DA may include short sides extending in a first direction DR1 and long sides extending in a second direction DR2. The non-display area NDA may surround the display area DA. The non-display area NDA may be located at one side in the first direction DR1, the other side in the first direction DR1, one side in the second direction DR2, and the other side in the second direction DR2 of the display area DA, but embodiments of the present disclosure are not limited thereto.

The non-display area NDA located at the other side of the display area DA in the second direction DR2 may extend further from a central portion of the other side of the display area DA in the second direction DR2 toward the other side in the second direction DR2. A width of the non-display area NDA in the first direction DR1 further extending from the central portion of the other side of the display area DA in the second direction DR2 toward the other side in the second direction DR2 may be smaller than a width of the non-display area NDA in the first direction DR1 adjacent to the other side of the display area DA in the second direction DR2. However, the present disclosure is not limited thereto. For example, referring to FIG. 2, at a lower side of the display area DA, a width of a portion of the non-display area NDA directly adjacent to the display area DA in the first direction DR1 is greater than widths of other portions of the non-display area NDA at the lower side of the display area DA. However, the present disclosure is not limited thereto.

The display apparatus 10 may include a first region MR, a second region SR, and a third region BR between the first region MR and the second region SR. The display area DA and the non-display area NDA surrounding four surfaces of the display area DA may form the first region MR. The portion extending further from the central portion of the other side of the display area DA in the second direction DR2 toward the other side of the second direction DR2 may form the third region BR and the second region SR. The third region BR may be disposed between the second region SR and the first region MR. The second region SR may include a first pad area PA1 and a second pad area PA2 located at an end portion of the other side of the second region SR in the second direction DR2. The touch panel TISP may have substantially the same size as the first region MR, but embodiments of the present disclosure are not limited thereto. For example, the first region MR may be a main region or a display region, but is not limited thereto. For example, the second region SR may be a sub-region, but is not limited thereto. For example, the third region BR may be a bending region or a variable region, but is not limited thereto.

The display apparatus 10 may further include an integrated IC SRIC disposed in the first pad area PA1 and a printed circuit board FPCB attached to the second pad area PA2.

A plurality of pads connected to the integrated IC SRIC and the printed circuit board FPCB may be disposed in each of the first pad area PA1 and the second pad area PA2. The integrated IC SRIC may be formed, for example, in the form of a driving chip (IC), but is not limited thereto. One embodiment describes that the integrated IC SRIC is disposed in a chip-on-plastic manner that the integrated IC SRIC is directly mounted on the display panel DISP.

A controller may be disposed on the printed circuit board FPCB. A controller may include a plurality of controllers. For example, the controller may include a first controller and a second controller spaced apart from the first controller. For example, the first controller may be the display controller DSIP, but embodiments of the present disclosure are not limited thereto. The second controller may include the touch controller TSIP, but embodiments of the present disclosure are not limited thereto. The printed circuit board FPCB may further include a connector CN and may be electrically connected to a main circuit board, etc., through the connector CN, but embodiments of the present disclosure are not limited thereto.

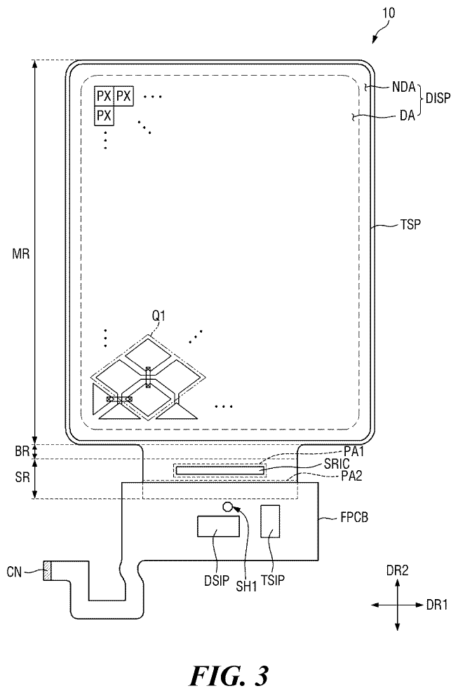

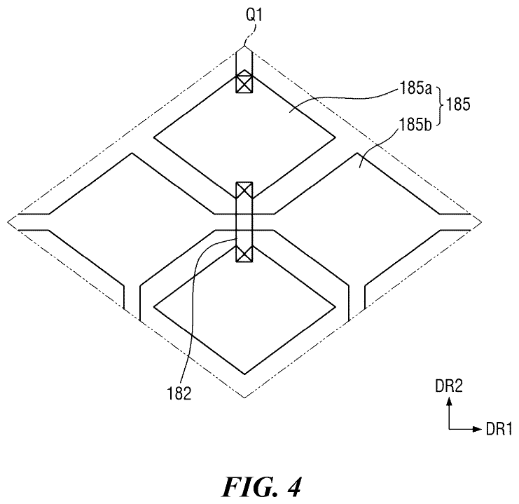

FIG. 3 is a plan view showing a touch panel and the printed circuit board of the display apparatus according to FIG. 1. FIG. 4 is an enlarged plan view of area Q1 in FIG. 3.

Referring to FIGS. 1 to 4, the touch panel TSP may include a sensor area SA in which touch electrodes 185 and 182 for detecting a user's touch in a capacitive manner are disposed, and a non-sensor area NSA located near the sensor area SA. The touch panel TSP may sense the user's touch in a self-capacitance method or a mutual capacitance method, but embodiments of the present disclosure are not limited thereto. In the present specification, the touch panel TSP is described as sensing the user's touch in the mutual capacitance method, but embodiments of the present disclosure are not limited thereto.

The plurality of touch electrodes 185 and 182 may generate a mutual electrostatic capacitance or a self-electrostatic capacitance to detect the object or person's touch. The plurality of touch electrodes 185 and 182 may include the first touch electrode 185 and the second touch electrode 182. The first touch electrode 185 may include a la touch electrode 185a extending in the second direction DR2 and a 1b touch electrode 185b extending in the first direction DR1 that differs from the second direction DR2. The la touch electrode 185a and the 1b touch electrode 185b may be located coplanarly, and the la touch electrodes 185a adjacent to each other may be electrically connected through the second touch electrode 182 to avoid a short with the 1b touch electrode 185b.

For example, a touch driving signal may be applied to the la touch electrode 185a, and a touch sensing signal may be detected from the 1b touch electrode 185b. The touch driving circuit TDC may detect the touch sensing signal and output sensing data, and the touch controller TSIP may detect the presence or absence of touch and/or touch coordinates based on the sensing data.

The touch panel TSP may be manufactured separately from the display panel DISP and bonded to the display panel DISP or built into the display panel DISP, but embodiments of the present disclosure are not limited thereto.

For convenience of description, the following description will focus on the case where the touch panel TSP is built into the display panel DISP.

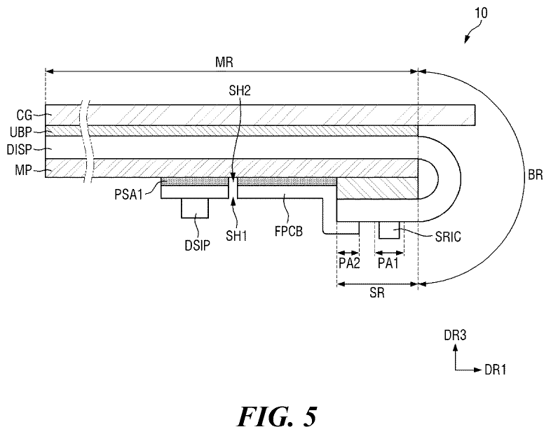

FIG. 5 is a cross-sectional view showing a bent state of the display apparatus according to an embodiment of the present disclosure.

Referring to FIG. 5, the display panel DISP may be bent in the third region BR. The second region SR of the display panel DISP may overlap the first region MR in the thickness direction. A plate layer MP may be further disposed on a lower surface of the first region MR and a lower surface (upper surface after bending) of the second region SR of the display panel DISP. The plate layer MP may not be disposed in the third region BR, but embodiments of the present disclosure are not limited thereto. The plate layer MP may include stainless steel, but embodiments of the present disclosure are not limited thereto. A back-plate layer may be further disposed between the plate layer MP and the display panel DISP, but embodiments of the present disclosure are not limited thereto.

The display apparatus 10 may further include a cover layer CG on the display panel DISP and a coupling layer UBP that couples the cover layer CG with the display panel DISP. For example, the coupling layer UBP may include an adhesive. The adhesive may be an optically cleared resin (OCR), an optically cleared adhesive (OCA), or a pressure sensitive adhesive (PSA), but embodiments of the present disclosure are not limited thereto.

The cover layer CG may be formed of a glass material including glass or quartz, but embodiments of the present disclosure are not limited thereto. The cover layer CG may be disposed on the display panel DISP to protect members (e.g., lower structures) disposed under the cover layer CG from the outside. The cover layer CG may be a cover layer formed by chemical reinforcement, but embodiments of the present disclosure are not limited thereto. The cover layer CG may be a cover window, a window cover, or a cover member, but embodiments of the present disclosure are not limited thereto. A polarizing layer may be further disposed between the cover layer CG and the display panel DISP, but embodiments of the present disclosure are not limited thereto.

The printed circuit board FPCB may overlap the first region MR. The printed circuit board FPCB may be disposed or attached to the plate layer MP on the first region MR. A first coupling layer PSA1 may be disposed between the printed circuit board FPCB and the plate layer MP of the first region MR. The first coupling layer may include an optically cleared resin (OCR), an optically cleared adhesive (OCA), or a pressure-sensitive adhesive, but embodiments of the present disclosure are not limited thereto.

The display controller DSIP may be disposed at one side of the printed circuit board FPCB. The one side of the printed circuit board FPCB may be a surface opposite to the other surface attached to the plate layer MP. Although FIG. 5 shows that only the display controller DSIP is disposed at the one side of the printed circuit board FPCB, the touch controller TSIP may also be disposed together.

The printed circuit board FPCB may include a first hole SH1. The first coupling layer PSA1 may include a second hole SH2. The first hole SH1 and the second hole SH2 may overlap each other. The first hole SH1 and the second hole SH2 may have the same size, but embodiments of the present disclosure are not limited thereto. The size of the second hole SH2 may be greater than the size of the first hole SH1, but embodiments of the present disclosure are not limited thereto. The second hole SH2 may cover the first hole SH1, but embodiments of the present disclosure are not limited thereto. For example, the second hole SH2 may fully cover the first hole SH1, but embodiments of the present disclosure are not limited thereto.

According to the present specification, the display panel DISP may include the third region BR, and the display panel DISP may be bent in the bending region BR. Therefore, it is possible to reduce the bezel area of the display panel DISP.

According to the present specification, the printed circuit board FPCB may be attached to the end portion of the bent display panel DISP, and the printed circuit board FPCB may be attached to the plate layer MP through the first coupling layer PSA1. Therefore, it is possible to minimize the movement of the printed circuit board FPCB. Therefore, it is possible to minimize physical interference between the printed circuit board FPCB and set components, reinforce durability of the display apparatus, and increase the lifetime of the display apparatus.

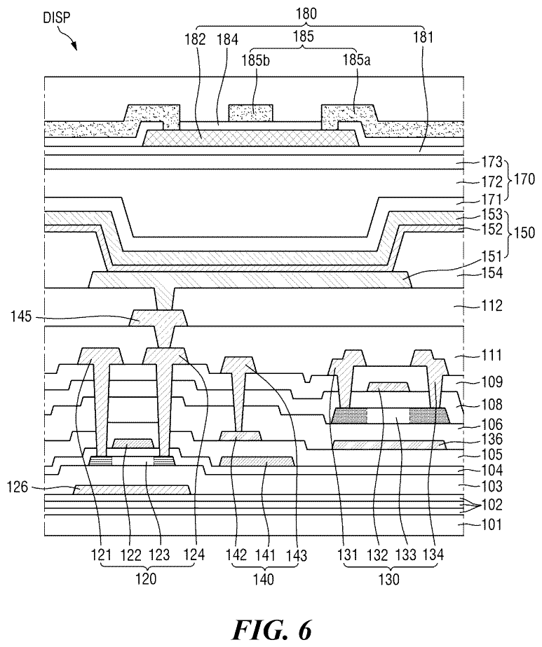

FIG. 6 is a cross-sectional view of a display panel of FIG. 5.

Referring to FIG. 6, the display panel DISP may include a substrate 101, a first thin film transistor 120, a second thin film transistor 130, a light emitting part 150, an encapsulation part 170, and a touch part 180.

The substrate 101 may include one or more plastic materials. For example, the substrate 101 may be a multi-substrate including a plurality of plastic materials such as polyimide, but embodiments of the present disclosure are not limited thereto. In some exemplary embodiments, the substrate 101 may be formed of a flexible polymer film. For example, the flexible polymer film may be formed of any one of polyimide (PI), polyethylene terephthalate (PET), acrylonitrile-butadiene-styrene copolymer (ABS), polymethyl methacrylate (PMMA), polyethylene naphthalate (PEN), polycarbonate (PC), polyethersulfone (PES), polyarylate (PAR), polysulfone (PSF), cyclic olefin copolymer (COC), triacetylcellulose (TAC), polyvinyl alcohol (PVA), and polystyrene (PS). However, the present disclosure is not limited thereto.

The buffer layer 102 may be disposed on the substrate 101. The buffer layer 102 may minimize or reduce the diffusion of moisture or oxygen permeating the substrate 101. The buffer layer 102 may be formed by alternately stacking silicone nitride (SiNx) and silicone oxide (SiOx) at least once, but embodiments of the present disclosure are not limited thereto.

The buffer layer 102 may have a single-layer or a multilayer structure. For example, the buffer layer 102 may have a stacked structure including a film formed of silicon nitride (SiNx) and a film formed of silicon oxide (SiOx). For example, the buffer layer 102 may be configured as a single layer or multilayer formed of at least one of silicon nitride (SiNx) and silicon oxide (SiOx). For example, the buffer layer 102 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto. However, the buffer layer 102 may be excluded in accordance with the structure or properties of the display device. However, the present disclosure is not limited thereto.

A first light blocking layer 126 may be disposed on the buffer layer 102. The first light blocking layer 126 can prevent light from being transmitted through a first semiconductor layer 123 of the first thin film transistor 120. For example, the first semiconductor layer 123 may be disposed to overlap the first light blocking layer 126. The first light blocking layer 126 may be formed of a single layer or multiple layers formed of any one of molybdenum (Mo), aluminum (Al), chromium (Cr), nickel (Ni), neodymium (Nd), and copper (Cu) or an alloy thereof, but embodiments of the present disclosure are not limited thereto.

A first insulating layer 103 may be disposed on the first light blocking layer 126. The first insulating layer 103 may prevent a short between a component of the first thin film transistor 120 and the first light blocking layer 126. The first insulating layer 103 may be formed of the same material as the buffer layer 102, but embodiments of the present disclosure are not limited thereto. For example, the first insulating layer 103 may be formed of an inorganic material, such as silicone nitride (SiNx) or silicone oxide (SiOx), but embodiments of the present disclosure are not limited thereto. For example, the first insulating layer 103 may be configured as a single layer or multilayer formed of at least one of silicon nitride (SiNx) and silicon oxide (SiOx). For example, the first insulating layer 103 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto.

The first thin film transistor 120 may be disposed on the first insulating layer 103. The first thin film transistor 120 may include a first source electrode 121, a first gate electrode 122, the first semiconductor layer 123, and a first drain electrode 124.

The first semiconductor layer 123 may be disposed on the first insulating layer 103. The first semiconductor layer 123 maybe formed of a semiconductor material, such as an oxide semiconductor, amorphous semiconductor, or polycrystalline semiconductor, but embodiments of the present disclosure are not limited thereto.

The oxide semiconductor material may have an excellent effect of preventing a leakage current and relatively inexpensive manufacturing cost. The oxide semiconductor may be formed of a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor may include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto.

The polycrystalline semiconductor material has a fast movement speed of carriers such as electrons and holes and thus has high mobility, and has low energy power consumption and superior reliability. The polycrystalline semiconductor may be formed of polycrystalline silicon (poly-Si) or low temperature polycrystalline silicon, but is not limited thereto.

The amorphous semiconductor material may be formed of amorphous silicon (a-Si), but is not limited thereto.

The first semiconductor layer 123 may include a channel area, a source area, and a drain area.

Since the low temperature polycrystalline silicon semiconductor layer or the polycrystalline silicon semiconductor layer has higher mobility than the amorphous semiconductor layer and the oxide semiconductor layer, power consumption may be low and reliability may be excellent. Therefore, the driving transistor may be formed of the low temperature polycrystalline silicone semiconductor layer or the polycrystalline silicone semiconductor layer, but embodiments of the present disclosure are not limited thereto.

A second insulating layer 104 may be disposed on the first semiconductor layer 123. The second insulating layer 104 may be formed of the same material as the first insulating layer 103, but embodiments of the present disclosure are not limited thereto. For example, the second insulating layer 104 may be configured as a single layer or multilayer formed of at least one of silicon nitride (SiNx) and silicon oxide (SiOx). For example, the second insulating layer 104 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto. The second insulating layer 104 may prevent a short between the first semiconductor layer 123 and another component of the first thin film transistor 120.

A first gate electrode 122 may be disposed on the second insulating layer 104. The first gate electrode 122 may be disposed on the second insulating layer 104 to overlap the channel area of the first semiconductor layer 123. The first gate electrode 122 may be formed of a single layer or multiple layers formed of molybdenum (Mo), copper (Cu), titanium (Ti), aluminum (Al), chromium (Cr), gold (Au), nickel (Ni), neodymium (Nd), or compounds thereof, but embodiments of the present disclosure are not limited thereto. The first gate electrode 122 may be disposed together with the gate line, but embodiments of the present disclosure are not limited thereto.

A third insulating layer 105 may be disposed on the first gate electrode 122. The third insulating layer 105 may be formed of the same material as the first insulating layer 103 or the second insulating layer 104, but embodiments of the present disclosure are not limited thereto. For example, the third insulating layer 105 may be configured as a single layer or multilayer formed of at least one of silicon nitride (SiNx) and silicon oxide (SiOx). For example, the third insulating layer 105 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto.

The first source electrode 121 and the first drain electrode 124 may be disposed on the third insulating layer 105.

The first source electrode 121 and the first drain electrode 124 may be electrically connected to the first semiconductor layer 123 through contact holes. The first source electrode 121 and the first drain electrode 124 may be formed of a metal material. For example, each of the first source electrode 121 and the first drain electrode 124 may be formed of a single layer or multiple layers formed of any one of molybdenum (Mo), aluminum (Al), chromium (Cr), gold (Au), titanium (Ti), nickel (Ni), neodymium (Nd), and copper (Cu) or an alloy thereof, but embodiments of the present disclosure are not limited thereto.

The first source electrode 121 and the first drain electrode 124 may be disposed together with data lines. For example, the data line may be formed of the same material as the first source electrode 121 and the first drain electrode 124 and formed coplanarly therewith, but embodiments of the present disclosure are not limited thereto. For example, the data line may be formed of a different material from the first source electrode 121 and the first drain electrode 124.

The storage electrode 140 may be disposed to be spaced apart from the first thin film transistor 120. The storage electrode 140 may include a first storage electrode 141, a second storage electrode 142, and a third storage electrode 143.

The first storage electrode 141 may be formed of the same material as the first gate electrode 122 and may be formed coplanarly therewith, but embodiments of the present disclosure are not limited thereto. For example, the first storage electrode 141 may be formed of a different material from the first gate electrode 122.

The second storage electrode 142 may be disposed on the first storage electrode 141. The second storage electrode 142 may be disposed on the third insulating layer 105, and the third insulating layer 105 between the first storage electrode 141 and the second storage electrode 142 may be used as a dielectric to generate a capacitance. The second storage electrode 142 may be formed of the same material as the first storage electrode 141, but embodiments of the present disclosure are not limited thereto. For example, the second storage electrode 142 may be formed of a different material from the first storage electrode 141.

The second thin film transistor 130 may be disposed to be spaced apart from the first thin film transistor 120 and the storage electrode 140. The second thin film transistor 130 may include a second source electrode 131, a second gate electrode 132, a second semiconductor layer 133, and a second drain electrode 134.

A second light blocking layer 136 may be disposed coplanarly with the second storage electrode 142.

The second light blocking layer 136 can prevent light directed to the second semiconductor layer 133 similar to the first light blocking layer 126, thereby extending the lifetime of the second thin film transistor 130. For example, the second semiconductor layer 133 may be disposed to overlap the second light blocking layer 136.

A fourth insulating layer 106 may be disposed on the second light blocking layer 136. The fourth insulating layer 106 may be formed of the same material as the first insulating layer 103, the second insulating layer 104, or the third insulating layer 105, but embodiments of the present disclosure are not limited thereto.

For example, the fourth insulating layer 106 may be configured as a single layer or multilayer formed of at least one of silicon nitride (SiNx) and silicon oxide (SiOx). For example, the fourth insulating layer 106 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto.

The second semiconductor layer 133 may be disposed on the fourth insulating layer 106. The second semiconductor layer 133 may include a source area, a drain area, and a channel area between the source area and the drain area.

The second semiconductor layer 133 may be formed of a semiconductor material, such as an oxide semiconductor, amorphous semiconductor, or polycrystalline semiconductor, but embodiments of the present disclosure are not limited thereto.

The oxide semiconductor material may have an excellent effect of preventing a leakage current and relatively inexpensive manufacturing cost. The oxide semiconductor may be formed of a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor may include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto.

The polycrystalline semiconductor material has a fast movement speed of carriers such as electrons and holes and thus has high mobility, and has low energy power consumption and superior reliability. The polycrystalline semiconductor may be formed of polycrystalline silicon (poly-Si) or low temperature polycrystalline silicon, but is not limited thereto.

The amorphous semiconductor material may be formed of amorphous silicon (a-Si), but is not limited thereto.

A fifth insulating layer 108 may be disposed on the second semiconductor layer 133. The fifth insulating layer 108 may be formed of the same material as the first insulating layer 103, the second insulating layer 104, the third insulating layer 105, or the fourth insulating layer 106, but embodiments of the present disclosure are not limited thereto. For example, the fifth insulating layer 108 may be configured as a single layer or multilayer formed of at least one of silicon nitride (SiNx) and silicon oxide (SiOx). For example, the fifth insulating layer 108 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto.

A second gate electrode 132 may be disposed on the fifth insulating layer 108.

The second gate electrode 132 may be formed of the same material as the first gate electrode 122. For example, the second gate electrode 132 may be formed of a single layer or multiple layers formed of molybdenum (Mo), copper (Cu), titanium (Ti), aluminum (Al), chromium (Cr), gold (Au), nickel (Ni), neodymium (Nd), or compounds thereof, but embodiments of the present disclosure are not limited thereto.

A sixth insulating layer 109 may be disposed on the second gate electrode 132. The sixth insulating layer 109 may be formed of the same material as the first insulating layer 103, the second insulating layer 104, the third insulating layer 105, the fourth insulating layer 106, or the fifth insulating layer 108, but embodiments of the present disclosure are not limited thereto. For example, the sixth insulating layer 109 may be configured as a single layer or multilayer formed of at least one of silicon nitride (SiNx) and silicon oxide (SiOx). For example, the sixth insulating layer 109 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto.

The first source electrode 121, the first drain electrode 124, the third storage electrode 143, the second source electrode 131, and the second drain electrode 134 may be disposed on the sixth insulating layer 109.

The third storage electrode 143, the second source electrode 131, and the second drain electrode 134 may be formed of the same material as the first source electrode 121 and the first drain electrode 124 and disposed coplanarly therewith, but embodiments of the present disclosure are not limited thereto. For example, the third storage electrode 143, the second source electrode 131, and the second drain electrode 134 may be formed of a single layer or multiple layers formed of any one of molybdenum (Mo), aluminum (Al), chromium (Cr), gold (Au), titanium (Ti), nickel (Ni), neodymium (Nd), and copper (Cu) or an alloy thereof, but embodiments of the present disclosure are not limited thereto. For example, at least one of the third storage electrode 143, the second source electrode 131, and the second drain electrode 134 may be formed of a different material from the first source electrode 121 and the first drain electrode 124.

The first thin film transistor 120 may be a driving transistor, and the second thin film transistor 130 may be a switching transistor, but embodiments of the present disclosure are not limited thereto.

A first protective layer 111 may be disposed on the first source electrode 121 and the first drain electrode 124.

The first protective layer 111 may planarize an upper portion of the first thin film transistor 120 and protect the first thin film transistor 120. The first protective layer 111 may be formed of an organic material. For example, the first protective layer 111 may be formed of an organic material containing an acrylic resin, an epoxy resin, a phenolic resin, a polyamide resin, or a polyimide resin, but embodiments of the present disclosure are not limited thereto.

A second protective layer 112 may be disposed on the first protective layer 111. The second protective layer 112 may be formed of the same material as the first protective layer 111, for example, the second protective layer 112 may be formed of an organic material containing an acrylic resin, an epoxy resin, a phenolic resin, a polyamide resin, or a polyimide resin, but embodiments of the present disclosure are not limited thereto. For example, the second protective layer 112 may be formed of a different material from the first protective layer 111.

A connection electrode 145 may be disposed between the first protective layer 111 and the second protective layer 112.

The connection electrode 145 may electrically connect the first thin film transistor 120 with the light emitting part 150. The connection electrode 145 may be formed of the same material as the first source electrode 121 and the first drain electrode 124, but embodiments of the present disclosure are not limited thereto. For example, the connection electrode 145 may be formed of a different material from the first source electrode 121 and the first drain electrode 124.

The connection electrode 145 may be formed of a single layer or multiple layers formed of any one of molybdenum (Mo), aluminum (Al), chromium (Cr), gold (Au), titanium (Ti), nickel (Ni), neodymium (Nd), and copper (Cu) or an alloy thereof, but embodiments of the present disclosure are not limited thereto.

The light emitting part 150 may be disposed on the second protective layer 112. The light emitting part 150 may include an anode electrode 151, an organic layer 152, and a cathode electrode 153.

The anode electrode 151 may be disposed on the second protective layer 112. The anode electrode 151 may be electrically connected to the first thin film transistor 120 through a contact hole formed in the second protective layer 112. The anode electrode 151 may be a reflective electrode that reflects light, but embodiments of the present disclosure are not limited thereto. The anode electrode 151 may include a metal material with high reflectivity, such as a stacking structure (Ti/Al/Ti) of aluminum (Al) and titanium (Ti), a stacking structure (ITO/AI/ITO) of aluminum (Al) and indium tin oxide (ITO), or an APC alloy, and may be formed of a single layer or multiple layers, but embodiments of the present disclosure are not limited thereto.

The organic layer 152 may be disposed on the anode electrode 151. The organic layer 152 may include one or more light emitting structures (or light emitting elements or elements) stacked on the anode electrode 151 in the order or reverse order of a hole transport layer and an electron transport layer. For example, the hole transfer layer may include a hole transport layer, a hole injection layer, an electron blocking layer, a p-type charge generation layer, or the like, but embodiments of the present disclosure are not limited thereto. For example, the electron transfer layer may include an electron transport layer, an electron injection layer, a hole blocking layer, an n-type charge generation layer, or the like, but embodiments of the present disclosure are not limited thereto. The organic layer 152 may be an organic light emitting layer. Alternatively, the organic light emitting layer may be replaced by an inorganic light emitting layer, a quantum dot light emitting layer, a micro light emitting diode, a micro mini light emitting diode, or the like, but embodiments of the present disclosure area not limited thereto. For example, the organic layer 152 of the display panel DISP according to an embodiment of the present disclosure may include the organic light emitting layer. The organic layer 152 may include a red light emitting layer, a green light emitting layer, and a blue light emitting layer. The organic layer 152 may be a white light emitting layer, but embodiments of the present disclosure are not limited thereto.

The cathode electrode 153 may be disposed on the organic layer 152. The cathode electrode 153 may be a transparent electrode that reflects light, but embodiments of the present disclosure are not limited thereto. For example, the cathode electrode 153 may include a transparent conductive material, such as indium tin oxide (ITO) or indium zinc oxide (IZO), or a metal that transmits visible light.

The bank 154 may be disposed to expose the anode electrode 151. The bank 154 may define an opening (or an emission area) of the pixel and may be disposed to cover an edge portion of the anode electrode 151.

Each sub-pixel may include a red emission area, a green emission area, and a blue emission area. For another example, the pixel may further include a white emission area, but is not limited thereto. The bank 154 may be formed of a material containing black pigment, or an organic material such as a benzocyclobutene resin, a polyimide resin, an acrylic resin, or a photosensitive polymer, but embodiments of the present disclosure are not limited thereto. When the bank 154 is formed of a material containing black pigment or black dye, it may be a black bank. When the bank is formed of a material containing black pigment or black dye, it is possible to block light from the outside or light reflected from the outside, thereby further increasing the brightness of the display apparatus.

The encapsulation part 170 may be disposed on the bank 154 or the light emitting part 150. The encapsulation part 170 may include one or more insulating layers. For example, the encapsulation part 170 may include a first encapsulation layer 171, a second encapsulation layer 172 disposed on the first encapsulation layer 171, and a third encapsulation layer 173 disposed on the second encapsulation layer 172. The encapsulation part 170 may include one or more inorganic layers and one or more organic layers. Therefore, damage to the light-emitting elements of the display apparatus caused by moisture and impact from the outside may be further effectively suppressed. For example, the first encapsulation layer 171 and the third encapsulation layer 173 may include an inorganic material, and the second encapsulation layer 172 may include an organic material, but embodiments of the present disclosure are not limited thereto.

For example, the first encapsulation layer to the third encapsulation layer may be sequentially stacked on the cathode electrode 153, the first encapsulation layer and the third encapsulation layer may be formed of an inorganic film layer including an inorganic material, and the second encapsulation layer may be formed of an organic film layer including an organic material.

The first encapsulation layer may be formed at the lowermost end of the encapsulation layer to be in contact with the upper surface of the cathode electrode 153. The first encapsulation layer may be formed of a material such as silicon nitride (SiNx), silicon oxide (SiOx), silicon oxynitride (SiON), or aluminum oxide (Al₂O₃).

The second encapsulation layer may be formed on the first encapsulation layer. The second encapsulation layer may be formed of a material such as acrylic resin, epoxy resin, polyimide (PI), polyethylene (PE), or silicon oxycarbon (SiOC).

The third encapsulation layer may be formed on the second encapsulation layer. The third encapsulation layer may be formed of the same material as the first encapsulation layer, but not limited thereto, the third encapsulation layer may be formed of different material from the first encapsulation layer.

Meanwhile, the encapsulation layers are not limited to three layers, for example, n layers alternately stacked between inorganic encapsulation layer and organic encapsulation layer (where n is an integer greater than 3) may be included.

A touch buffer layer 181 may be disposed on the encapsulation part 170. For example, the touch buffer layer 181 may be disposed on the third encapsulation layer 173. The touch buffer layer 181 may be formed of the same material as the buffer layer 102, but embodiments of the present disclosure are not limited thereto. A touch insulating layer 184 may be disposed on the touch buffer layer 181. The touch insulating layer 184 may prevent a short between the touch electrodes. The touch insulating layer 184 may be formed of silicone oxide (SiOx), silicone nitride (SiNx), or multiple layers thereof, but embodiments of the present disclosure are not limited thereto. For example, the touch buffer layer 181 may be configured as a single layer or multilayer formed of at least one of silicon nitride (SiNx) and silicon oxide (SiOx). For example, the touch buffer layer 181 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto. A first touch electrode 185 may be disposed on the touch insulating layer 184.

A second touch electrode 182 may be disposed between the touch buffer layer 181 and the touch insulating layer 184.

The second touch electrode 182 may be electrically connected to the la touch electrode 185a through a contact hole formed in the touch insulating layer 184.

The first touch electrode 185 and the second touch electrode 182 may include a metal material. For example, the first touch electrode 185 and the second touch electrode 182 may be formed of titanium (Ti), nickel (Ni), aluminum (Al), or an alloy thereof and may be formed of a triple layer, such as titanium (Ti)/aluminum (Al)/titanium (Ti), but embodiments of the present disclosure are not limited thereto.

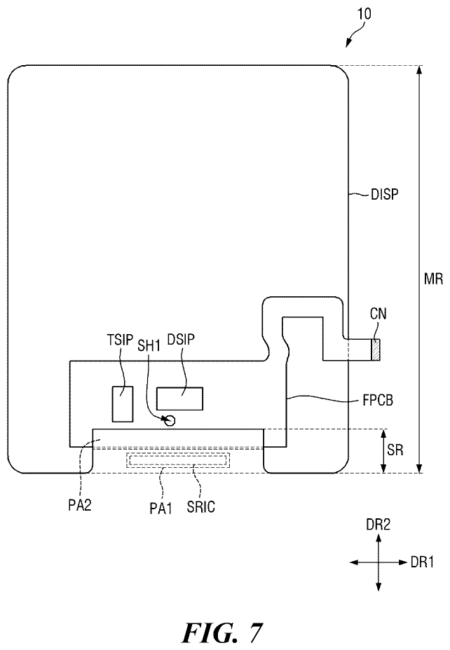

FIG. 7 is a rear view of the display apparatus according to FIG. 5. FIG. 7 shows a rear view of the display apparatus 10 viewed from the back of the display apparatus 10 of FIG. 2 after bent as shown in FIG. 5.

Referring to FIG. 7, the display apparatus 10 may include the display panel DISP and the printed circuit board FPCB. Since the description of the display panel DISP and the printed circuit board FPCB is substantially the same as the description with reference to FIGS. 1 to 5, repetitive descriptions thereof may be omitted or simplified.

The display apparatus 10 may include the first region MR and the second region SR. The second region SR may overlap the first region MR.

The second region SR may include a first pad region PA1 and a second pad region PA2. The integrated IC SRIC may be disposed in the first pad area PA1. The printed circuit board FPCB may be disposed in the second pad area PA2.

The display controller DSIP and the touch controller TSIP may be disposed on the printed circuit board FPCB. However, the embodiments of the present disclosure are not limited thereto, and only one controller may be disposed on the printed circuit board FPCB. The printed circuit board FPCB may further include a connector CN and may be electrically connected to a main circuit board, etc., through the connector CN, but embodiments of the present disclosure are not limited thereto.

The printed circuit board FPCB may include the first hole SH1. The first hole SH1 may be formed between the display controller DSIP and the second pad area PA2. For example, the printed circuit board FPCB may include the display controller DSIP, the touch controller TSIP, and the first hole SH1.

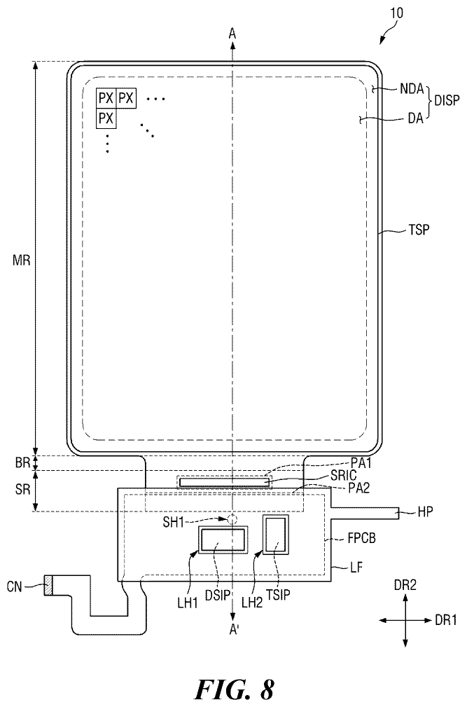

FIGS. 8 to 15 are views showing a method of manufacturing the display apparatus according to an embodiment of the present disclosure. FIGS. 8 to 15 respectively show a bending operation using the film, a first pressing operation, a peeling operation of the film, a second pressing operation, and a suction operation of the display panel DISP. In the description of the method of manufacturing the display apparatus according to an embodiment of the present disclosure with reference to FIGS. 8 to 15, reference may be made to FIGS. 1 to 7 together.

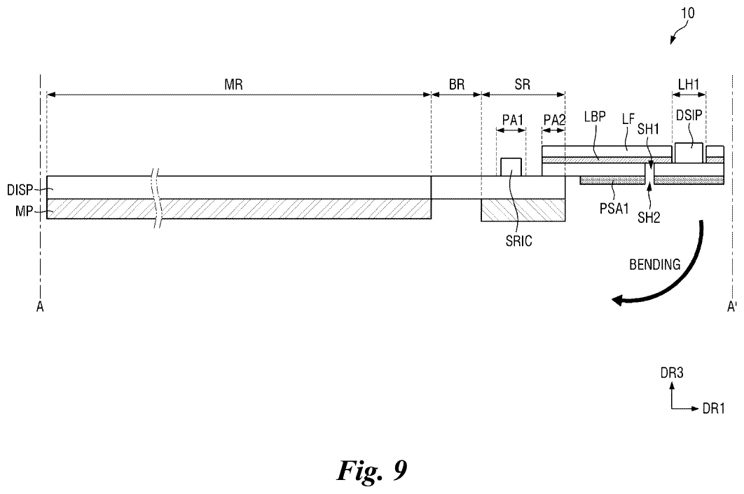

The attaching operation of a film LF will be described with reference to FIGS. 8 and 9. FIG. 9 is a cross-sectional view along line A-A′ in FIG. 8 according to an embodiment of the present disclosure.

As shown in FIGS. 2, 5, 8, and 9, the film LF is attached to the printed circuit board FPCB. The film LF may be a liner film LF, but is not limited thereto. The film LF may include polyethylene terephthalate (PET), polyimide (PI), or polycarbonate (PC), but embodiments of the present disclosure are not limited thereto. The film LF may include a tab part HP protruding to one side in the first direction DR1. For example, the film LF is a rectangular film having a length in the first direction DR1 and a width in the second direction DR2, and tab part HP extends from a side of the width of the film LF along the first direction DR1, however, the present disclosure is not limited thereto. The tab part HP may be formed of the same material as the film LF, but embodiments of the present disclosure are not limited thereto.

A liner hole may be formed in the film LF. The liner hole may overlap the controller on the printed circuit board FPCB. For example, a plurality of liner holes may be provided, but embodiments of the present disclosure are not limited thereto. The liner hole may include a first hole LH1 and a second hole LH2, but is not limited thereto. The first hole LH1 may overlap the display controller DSIP. The second hole LH2 may overlap the touch controller TSIP. The first hole LH1 and the second hole LH2 may be greater than widths of the display controller DSIP and touch controller TSIP that overlap respectively, but are not limited thereto. The display controller DSIP and the touch controller TSIP may be exposed to the outside in each of the liner holes LH1 and LH2. Each of the liner holes LH1 and LH2 may be a first hole or a second hole, but is not limited thereto.

The first hole SH1 may be formed in the printed circuit board FPCB, and the second hole SH2 may be formed in the first coupling layer PSA1.

A third coupling layer LBP may be disposed between the film LF and the printed circuit board FPCB. The film LF may be disposed or attached to one surface of the printed circuit board FPCB through the third coupling layer LBP. The film LF may also be disposed on the first hole SH1 and the second hole SH2. For example, the film LF may overlap the first hole SH1 and the second hole SH2. The film LF and the third coupling layer LBP may be disposed on the printed circuit board FPCB, and the film LF and the third coupling layer LBP may be disposed on the printed circuit board FPCB in the second region SR. For example, the film LF and the third coupling layer LBP may be disposed on the printed circuit board FPCB, and the film LF and the third coupling layer LBP may be disposed on the printed circuit board FPCB in the second pad area PA2. The printed circuit board FPCB may be thin and formed of a material having low storage modulus. In the bending the display panel DISP about the third region BR of the display panel DISP (marked by the arrow), when the printed circuit board FPCB is held, the thin printed circuit board FPCB can be damaged. Therefore, to prevent damage to the printed circuit board FPCB, the display panel DISP may be bent by holding the film LF in the bending of the display panel DISP.

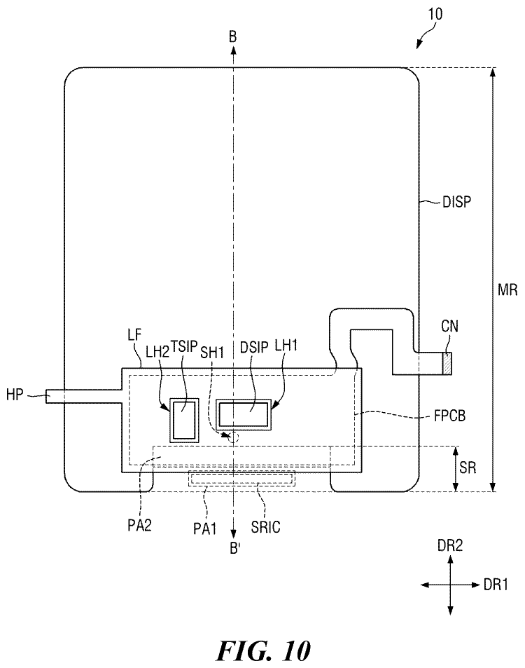

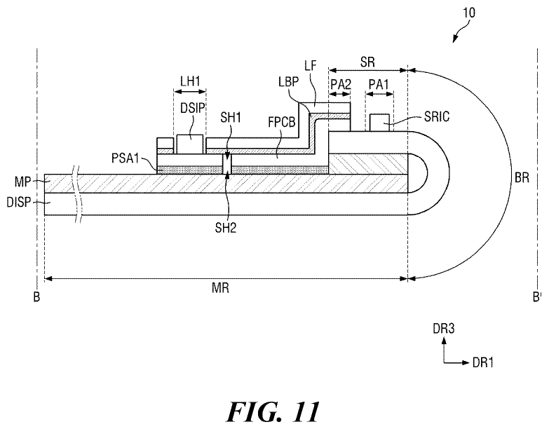

FIG. 10 shows a rear view of the display apparatus 10 after the bending of the display panel DISP according to FIG. 9. FIG. 11 is a cross-sectional view along line B-B′ in FIG. 10.

As shown in FIGS. 10 and 11, the film LF may be located in the rearmost direction of the display apparatus 10, and the display controller DISP and the touch controller TISP may be exposed toward the rear surface of the display apparatus 10 through the first hole LH1 and the second hole LH2 of the film LF.

The printed circuit board FPCB may be disposed or attached to the plate layer MP on the first region MR through the first coupling layer PSA1.

The film LF on the first region MR may be disposed or attached to one surface of the printed circuit board FPCB through the third coupling layer LBP. The film LF and the third coupling layer LBP may be disposed on the printed circuit board FPCB, and the film LF and the third coupling layer LBP may be disposed on the printed circuit board FPCB in the second region SR. For example, the film LF and the third coupling layer LBP may be disposed on the printed circuit board FPCB, and the film LF and the third coupling layer LBP may be disposed on the printed circuit board FPCB in the second pad area PA2.

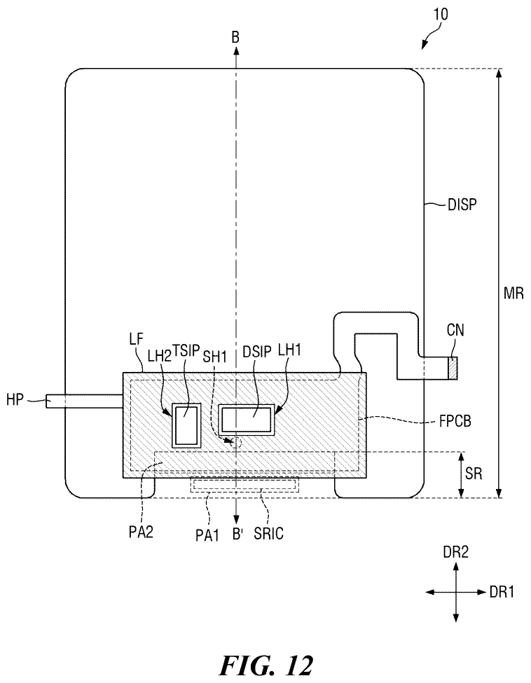

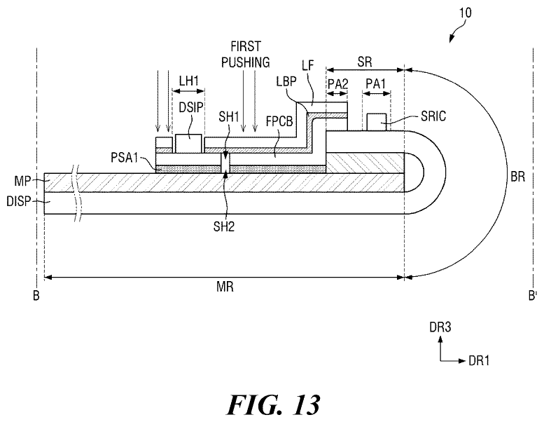

FIGS. 12 and 13 show a first pushing operation FIRST PUSHING between the printed circuit board FPCB and the plate layer MP.

As shown in FIGS. 12 and 13, the first pushing operation may be performed after arranging the film LF at the top. In the first pushing operation, a predetermined pressure may be applied to the one surface of the film LF. In the first pushing operation, it is possible to increase the adhesive force (or attaching force) between the printed circuit board FPCB and the plate layer MP on the first region MR. The first coupling layer PSA1 may be the pressure sensitive adhesive (PSA). For example, in the first pushing operation, the pressure applied to the film LF may be transmitted to the first coupling layer PSA1 to increase the adhesive force (or attaching force) between the printed circuit board FPCB and the plate layer MP in the first region MR. For example, the adhesive force (or attaching force) may be an adhesive strength, etc., but is not limited thereto.

In the first pushing operation, a predetermined pressure may not be applied to the first hole LH1 and the second hole LH2 of the film LF.

According to the present specification, in the pushing operation before the suction operation, it is possible to increase the adhesive force (or attaching force) between the printed circuit board FPCB and the plate layer MP by applying the predetermined pressure to the upper portion of the printed circuit board FPCB.

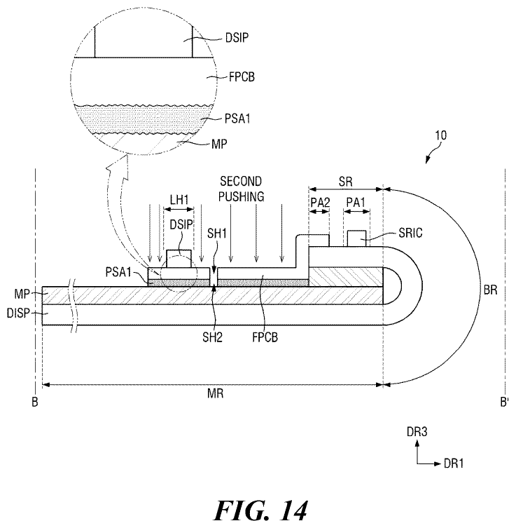

FIG. 14 shows the peeling operation of the film LF and the second pushing operation SECOND PUSHING.

As shown in FIG. 14, the film LF (see FIG. 13) and the third coupling layer LBP (see FIG. 13) may be peeled from the printed circuit board FPCB. To peel the film LF and the third coupling layer LBP from the printed circuit board FPCB, the adhesive force (or attaching force) of the third coupling layer LBP with the printed circuit board FPCB should be reduced. For example, after the adhesive force (or attaching force) of the third coupling layer LBP with the printed circuit board FPCB is reduced through ultraviolet (UV) radiation, heat radiation, etc., the liner film LF and the third coupling layer LBP may be peeled from the printed circuit board FPCB, but embodiments of the present disclosure are not limited thereto.

The predetermined pressure may be applied to the one surface of the printed circuit board FPCB from which the film LF and the third coupling layer LBP have been removed. In the second pushing operation, it is possible to increase the adhesive force (or attaching force) between the printed circuit board FPCB and the plate layer MP on the first region MR. After the second pushing operation, the adhesive force (or attaching force) between the printed circuit board FPCB and the plate layer MP may be higher than that of the first pushing operation.

Even in the second pushing operation, the predetermined pressure may not be applied to the area of the printed circuit board FPCB in which the display controller DSIP and the touch controller TSIP (see FIG. 12) are disposed.

Therefore, air bubbles may remain inside the first coupling layer PSA1, at the interface between the first coupling layer PSA1 and the printed circuit board FPCB, and at the interface between the first coupling layer PSA1 and the plate layer MP. Therefore, the adhesive force (or attaching force) between the printed circuit board FPCB and the plate layer MP in the area in which the controllers TSIP and DSIP (see FIG. 12) are disposed may not be sufficient. For example, in the pushing operation, due to heights of the controllers TSIP and DSIP (see FIG. 12), a pressure may be applied only to the remaining area of the printed circuit board FPCB excluding the area in which the controller is disposed. In this case, the adhesive force (or attaching force) between the area in which the controller of the printed circuit board FPCB is disposed and the plate layer MP can be reduced.

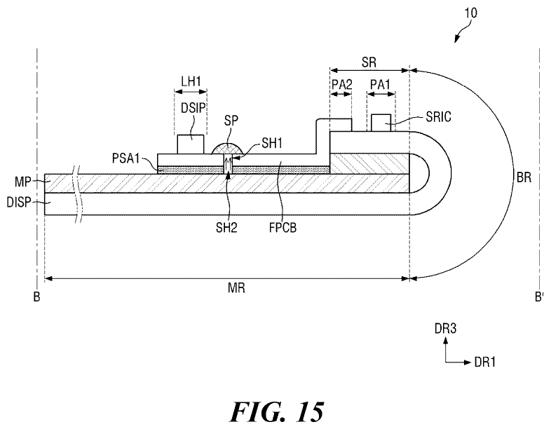

FIG. 15 shows the operation of suctioning the air bubbles inside the first coupling layer PSA1, at the interface between the first coupling layer PSA1 and the printed circuit board FPCB, and at the interface between the first coupling layer PSA1 and the plate layer MP through a suction device SP.

As shown in FIG. 15, the air bubbles remaining inside the first coupling layer PSA1, at the interface between the first coupling layer PSA1 and the printed circuit board FPCB, and at the interface between the first coupling layer PSA1 and the plate layer MP may be suctioned by the suction device SP through the second hole SH2 and the first hole SH1.

Through the suction operation of FIG. 15, it is possible to increase the adhesive force (or attaching force) between the printed circuit board FPCB and the plate layer MP in the area in which the controllers TSIP and DSIP (see FIG. 12) are disposed. Thereby, it is possible to minimize lifting from the plate layer MP of the printed circuit board FPCB.

In addition, since the air bubbles remaining inside the first coupling layer PSA1, at the interface between the first coupling layer PSA1 and the printed circuit board FPCB, and at the interface between the first coupling layer PSA1 and the plate layer MP are removed through the suction operation, uneven shapes formed on surfaces facing the plate layer MP of the first coupling layer PSA1 and the printed circuit board FPCB of FIG. 14 may be removed. Therefore, it is possible to improve external visibility of the display apparatus 10.

According to embodiments of the present disclosure, by adding the suction operation through the first hole SH1 of the printed circuit board FPCB after the pushing operation, it is possible to increase the adhesive force (or attaching force) between the area in which the controller of the printed circuit board FPCB is disposed and the plate layer MP.

According to the present specification, since the printed circuit board FPCB includes the first hole SH1, in the suction operation, the air bubbles remaining inside the first coupling layer PSA1, at the interface between the first coupling layer PSA1 and the printed circuit board FPCB, and at the interface between the first coupling layer PSA1 and the plate layer MP may be removed. Therefore, it is possible to minimize the lifting of the printed circuit board FPCB. Hereinafter, display apparatuses according to another embodiments of the present disclosure will be described. In the description of the embodiments below, detailed descriptions of components that are the same as or similar to the components described in FIGS. 1 to 15 will be omitted, or repetitive descriptions thereof will be omitted.

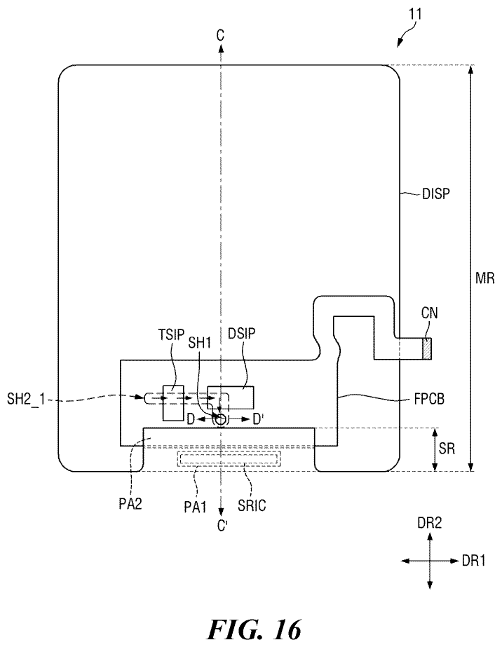

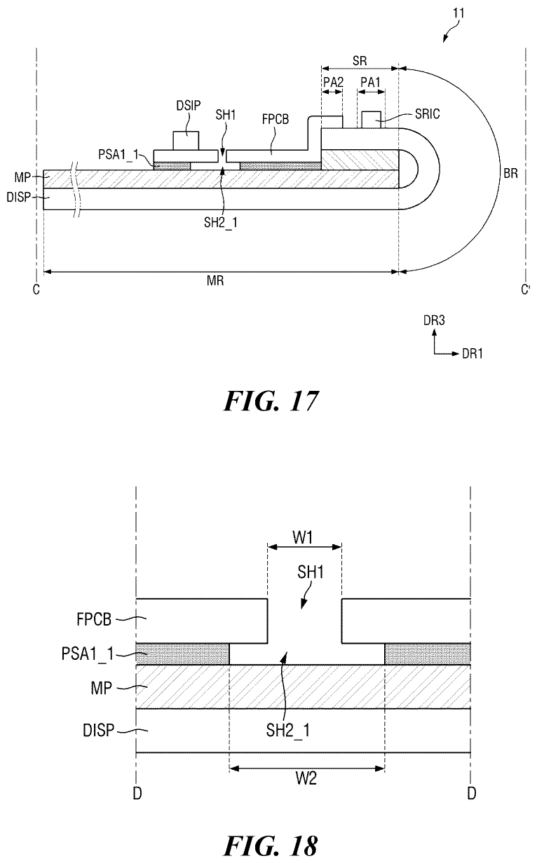

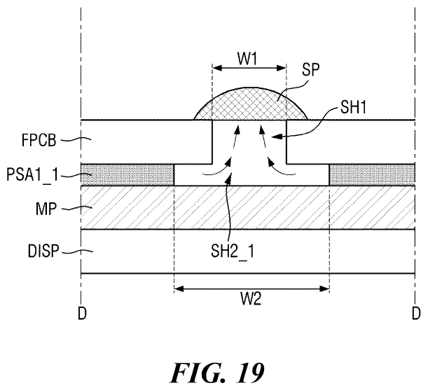

FIG. 16 is a rear view of a display apparatus according to another embodiment of the present disclosure. FIG. 17 is a cross-sectional view along line C-C′ in FIG. 16 according to another embodiment of the present disclosure. FIG. 18 is a cross-sectional view along line D-D′ in FIG. 16 according to another embodiment of the present disclosure. FIG. 19 is a cross-sectional view showing a suction process of the display apparatus according to another embodiment of the present disclosure.

Referring to FIGS. 16 to 19, a display apparatus 11 according to another embodiment of the present disclosure may include the display panel DISP and the printed circuit board FPCB. The display apparatus 11 may include the first region MR, the second region SR, and the third region BR. The second region SR may include the first pad area PA1 and the second pad area PA2. The integrated IC SRIC may be disposed in the first pad area PA1. The printed circuit board FPCB may include the first controller DSIP and the second controller TSIP. Since description of the display panel DISP, the printed circuit board FPCB, the integrated IC SRIC, the first controller DSIP, and the second controller TSIP is substantially the same as the description with reference to FIGS. 1 to 15, repetitive descriptions thereof can be omitted or simplified.

In the display apparatus 11 according to another embodiment of the present disclosure, a first coupling layer PSA1_1 may include a second hole SH2_1.

The second hole SH2_1 of the first coupling layer PSA1_1 may overlap the first hole SH1. The size of the second hole SH2_1 may be greater than that of the first hole SH1. The second hole SH2_1 may cover the first hole SH1. For example, the second hole SH2_1 may fully cover the first hole SH1. As shown in FIG. 16, the second hole SH2_1 may overlap the first hole SH1 and further extend to one side (or a portion) in the second direction DR2 to overlap the display controller DSIP. The second hole SH2_1 may overlap the first hole SH1 and extend further to the other side (or the other portion) in the first direction DR1 to overlap the touch controller TSIP.

As shown in FIG. 18, the first hole SH1 may have a first width W1, and the second hole SH2_1 may have a second width W2. The second width W2 may be greater than the first width W1. Since the second width W2 of the second hole SH2_1 is greater than the first width W1 of the first hole SH1 and the second hole SH2_1 covers the first hole SH1, an inner surface (or an inner side) of the printed circuit board FPCB may protrude inward (or in a direction toward the first hole SH1 more than an inner surface of the first coupling layer PSA1_1. The second hole SH2_1 may fully cover the first hole SH1. For example, the printed circuit board FPCB and the first coupling layer PSA1_1 may have a step toward a direction from the first coupling layer PSA_1 to the printed circuit board FPCB near the first hole SH1 and the second hole SH2_1. For example, the step may be a reversed step shape. Further, the first hole SH1 and the second hole SH2_1 may have a step in a direction of the second hole SH2_1 toward the first hole SH1. For example, the first hole SH1 and the second hole SH2_1 may have a step-shaped step in the direction of the second hole SH2_1 toward the first hole SH1. For example, the step between the printed circuit board FPCB and the first coupling layer PSA1_1 may have a different shape from the step between the first hole SH1 and the second hole SH2_1.

As shown in FIG. 19, since the first hole SH1 and the second hole SH2_1 have the step-shaped step, in the suction operation by the suction device SP, air bubbles suctioned through the suction device SP may generate a vortex (marked by an arrow) due to the step-shaped steps, thereby increasing the suction force of the suction device SP.

Further, since the second hole SH2_1 overlaps the display controller DSIP and the touch controller TSIP, the air bubbles remaining inside the first coupling layer PSA1_1, which overlaps the display controller DSIP and the touch controller TSIP, and/or at the interface between the first coupling layer PSA1_1 and the members MP and FPCB may be suctioned by the suction device SP through the second hole SH2_1. Therefore, it is possible to further increase the adhesive force (or attaching force) with the plate layer MP in the area in which the controllers DSIP and TSIP of the printed circuit board FPCB are disposed in the suction operation.

According to an embodiment of the present disclosure, the printed circuit board FPCB includes the first hole SH1 and the second hole SH2, and the second hole SH2 overlaps the controllers DSIP and TSIP, and thus, it is possible to increase the adhesive force (or attaching force) with the plate layer MP in the area in which the controllers DSIP and TSIP of the printed circuit board FPCB are disposed.

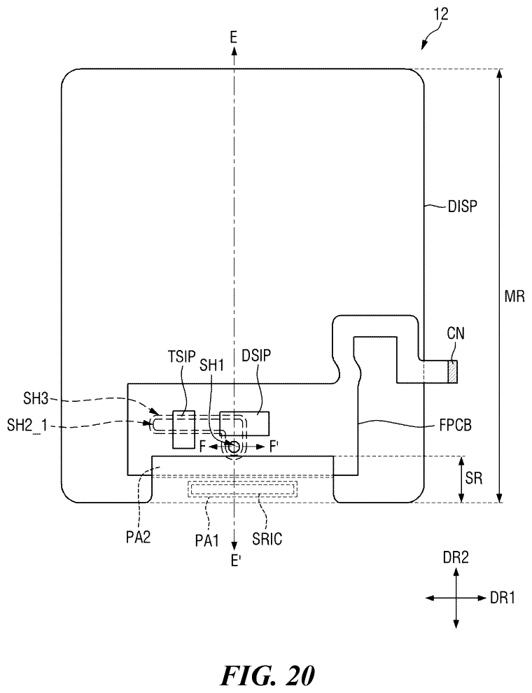

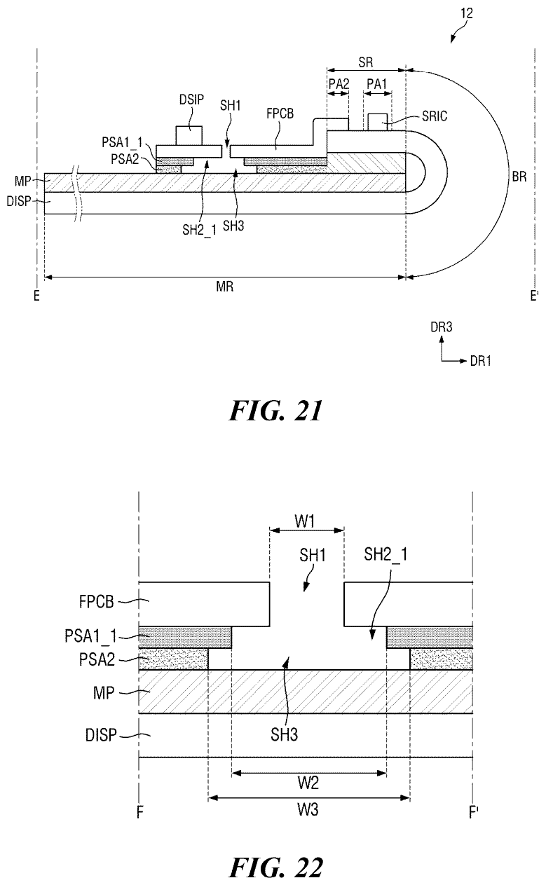

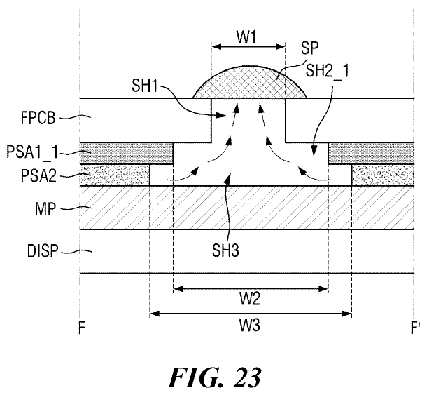

FIG. 20 is a rear view of a display apparatus according to another embodiment of the present disclosure. FIG. 21 is a cross-sectional view along line E-E′ in FIG. 20 according to another embodiment of the present disclosure. FIG. 22 is a cross-sectional view along line F-F′ in FIG. 20 according to another embodiment of the present disclosure. FIG. 23 is a cross-sectional view showing a suction process of the display apparatus according to another embodiment of the present disclosure.

Referring to FIGS. 20 to 23, a display apparatus 12 according to another embodiment of the present disclosure may include the display panel DISP and the printed circuit board FPCB. The display apparatus 11 may include the first region MR, the second region SR, and the third region BR. The second region SR may include the first pad area PA1 and the second pad area PA2. The integrated IC SRIC may be disposed at the first pad area PA1. The printed circuit board FPCB may include the first controller DSIP and the second controller TSIP. Since description of the display panel DISP, the printed circuit board FPCB, the integrated IC SRIC, the first controller DSIP, and the second controller TSIP is substantially the same as the description with reference to FIGS. 1 to 19, repetitive descriptions thereof can be omitted or simplified.

A display apparatus 12 according to another embodiment of the present disclosure may further include a second coupling layer PSA2.

The second coupling layer PSA2 may be disposed between the first coupling layer PSA1_1 and the plate layer MP. The second coupling layer PSA2 may include a third hole SH3.

The third hole SH3 may overlap the second hole SH2_1. The third hole SH3 may be greater than the second hole SH2_1. The third hole SH3 may cover the second hole SH2_1. For example, the third hole SH3 may fully cover the second hole SH2_1.

As shown in FIG. 20, the third hole SH3 may overlap the first hole SH1 and the second hole SH2_1. The third hole SH3 may further extend to one side (or a portion) in the second direction DR2 and overlap the display controller DSIP. The third hole SH3 may further extend to the other side (or the other portion) in the first direction DR1 and overlap the touch controller TSIP.

As shown in FIG. 22, the first hole SHI may have the first width W1, the second hole SH2 may have the second width W2, and the third hole SH3 may have a third width W3. The third width W3 may be greater than the second width W2 and the first width W1. Since the third width W3 of the third hole SH3 is greater than the second width W2 of the second hole SH2_1 and the third hole SH3 covers the second hole SH2_1, the inner surface (or the inner side) of the first coupling layer PSA1_1 may protrude inward (or in a direction toward the second hole SH2_1) more than the inner surface of the second coupling layer PSA2. The third hole SH3 may fully cover the second hole SH2_1. For example, the printed circuit board FPCB, the first coupling layer PSA1_1, and the second coupling layer PSA2 may have a step toward a direction from the second coupling layer PSA2 to the printed circuit board FPCB near the first hole SH1, the second hole SH2_1, and the third hole SH3. The step may be a reversed step shape. Further, the first hole SH1, the second hole SH2, and the third hole SH3 may have a step in a direction of the third hole SH3 toward the first hole SH1. The step may be a step shape. For example, the step of the printed circuit board FPCB, the first coupling layer PSA1_1, and the second coupling layer PSA2 may have a different shape from the step of the first hole SH1, the second hole SH2_1, and the third hole SH3.

As shown in FIG. 23, since the first hole SH1, the second hole SH2_1, and the third hole SH3 have the step-shaped step, in the suction operation using the suction device SP, the air bubbles suctioned through the suction device SP may generate a vortex (marked by the arrow) due to the step-shaped steps, thereby increasing the suction force of the suction device SP.

In addition, since the second hole SH2_1 and the third hole SH3 overlap the display controller DSIP and the touch controller TSIP, respectively, the air bubbles remaining inside the first coupling layer PSA1_1, which overlaps the display controller DSIP and the touch controller TSIP), and/or at the interface between the first coupling layer PSA1_1 and the members FPCB and PSA2 and the air bubbles remaining inside the second coupling layer PSA2, which overlaps the display controller DSIP and the touch controller TSIP, and/or at the interface between the second coupling layer PSA2 and the members PSA1 and MP may be suctioned by the suction device SP through the second hole SH2 and the third hole SH3, respectively. Therefore, it is possible to further increase the adhesive force (or attaching force) with the plate layer MP in the area in which the controllers DSIP and TSIP of the printed circuit board FPCB are disposed in the suction operation.

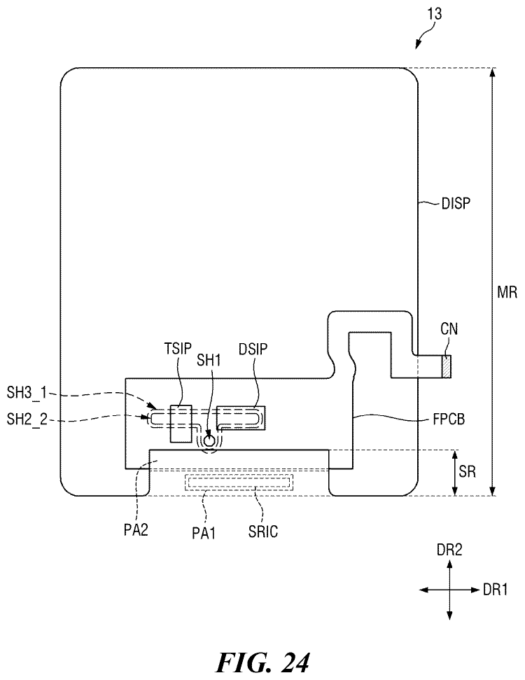

According to embodiments of the present disclosure, the second coupling layer PSA2 may include the third hole SH3, and the first hole SH1, the second hole SH2_1, and the third hole SH3 may have the step. In the suction operation, the air bubbles sucked through the suction device may generate a vortex due to the step, thereby increasing the suction force of the suction device. Therefore, it is possible to increase the adhesive force (or attaching force) with the plate layer MP in the area in which the controllers DSIP and TSIP of the printed circuit board FPCB are disposed. FIG. 24 is a rear view of a display apparatus according to another embodiment of the present disclosure.

Referring to FIG. 24, a display apparatus 13 according to another embodiment of the present disclosure may include the display panel DISP and the printed circuit board FPCB. The display apparatus 11 may include the first region MR, the second region SR, and the third region BR. The second region SR may include the first pad area PA1 and the second pad area PA2. The integrated IC SRIC may be disposed in the first pad area PA1. The printed circuit board FPCB may include the first controller DSIP and the second controller TSIP. Since description of the display panel DISP, the printed circuit board FPCB, the integrated IC SRIC, the first controller DSIP, and the second controller TSIP is substantially the same as the description with reference to FIGS. 1 to 23, repetitive descriptions thereof can be omitted or simplified.

In a display apparatus 13 according to another embodiment of the present disclosure, the first hole SH1 may be disposed between the display controller DSIP and the touch controller TSIP. A second hole SH2_2 is larger than the first hole SH1 and may cover or cover the first hole SH1. For example, the second hole SH2_2 may fully cover the first hole SH1. The third hole SH3_1 may be greater than the second hole SH2_2 and may cover the second hole SH2_2. For example, the third hole SH3_1 may fully cover the second hole SH2_2. The second hole SH2_2 and the third hole SH3_1 may each extend from the area in which the first hole SH1 is disposed to one side (or a portion) in the second direction DR2. The second hole SH2_2 and the third hole SH3_1 that extend to the one side (or a portion) of the second direction DR2 may extend to the other side (or the other portion) of the first direction DR1 and one side (or a portion) of the first direction DR1, respectively and overlap the touch controller TSIP and the display controller DSIP.

According to a display apparatus 13 according to another embodiment of the present disclosure, since the first hole SH1, the second hole SH2_2, and the third hole SH2_1 are each disposed between the touch controller TSIP and the display controller DSIP, it is possible to further increase the adhesive force (or attaching force) between the area between the touch controller TSIP and the display controller DSIP of the printed circuit board FPCB and the plate layer MP.

The display apparatus according to various embodiments of the present disclosure may be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an e-book, a portable multimedia player (PMP), a personal digital assistant (PDA), an MP3 player, a mobile medical apparatus, a desktop PC, a laptop PC, a netbook computer, a workstation, a navigation system, a vehicle display apparatus, a theater display apparatus, a television, a wallpaper apparatus, a signage apparatus, a game apparatus (or gaming apparatus), a laptop computer, a monitor, a camera, a camcorder, a home appliances, etc.

A display apparatus according to various embodiments of the present disclosure may be described as follows.

A display apparatus according to various embodiments of the present disclosure may include a display panel including a first region, a second region overlapping the first region, and a third region between the first region and the second region, a printed circuit board disposed at the first region and the second region, and a controller disposed on a printed circuit board. The display panel may be bent in the third region. The printed circuit board may include a first hole.

The display apparatus according to various embodiments of the present disclosure may further include a first coupling layer on the printed circuit board in a portion of the first region.

According to various embodiments of the present disclosure, the first coupling layer may include a second hole.

According to various embodiments of the present disclosure, the second hole may overlap the first hole.

According to various embodiments of the present disclosure, the first hole may have a first size and the second hole may have a second size equal to the first size.

According to various embodiments of the present disclosure, the second size may be greater than the first size to define a first step between the printed circuit board and the first coupling layer.

According to various embodiments of the present disclosure, the second hole may cover the first hole.

The display apparatus according to various embodiments of the present disclosure may further include a second coupling layer in a portion of the first coupling layer, and the second coupling layer including a third hole.

According to various embodiments of the present disclosure, the third hole may have a third size greater than the second size and may cover the second hole to define a second step between the first coupling layer and the second coupling layer.

According to various embodiments of the present disclosure, the second hole may overlap the controller.

A display apparatus according to various embodiments of the present disclosure may include a display panel including a first region, a second region overlapping the first region, and a third region between the first region and the second region, a printed circuit board disposed in the first region and the second region, and a controller disposed on the printed circuit board. The display panel may be bent in the third region. The printed circuit board may include a first hole. The controller may include a first controller and a second controller spaced apart from the first controller.

According to various embodiments of the present disclosure, the display apparatus may further include a first coupling layer disposed between the printed circuit board and the first region. The first coupling layer may include a pressure sensitive adhesive. The first coupling layer may include a second hole that cooperates with the first hole to define a step.

The display apparatus according to various embodiments of the present disclosure may further include a first coupling layer disposed between the printed circuit board and the first region and a plate layer disposed between the first coupling layer in the first region.

According to various exemplary embodiments of the present disclosure, the first hole may be disposed between the first controller and the second controller.

A display apparatus according to various embodiments of the present disclosure may include a display panel including a first region, a second region overlapping the first region, and a third region between the first region and the second region, a printed circuit board disposed at the first region and the second region and including a first hole, and a first coupling layer in a portion of the first region and being under the printed circuit board. The printed circuit board may include a first hole. The first coupling layer may include a second hole. The first hole and the second hole may overlap each other. The first hole and the second hole may have different sizes to define a step.

According to various embodiments of the present disclosure, a width of the second hole may be greater than a width of the first hole.

The display apparatus according to various embodiments of the present disclosure may further include a second coupling layer under the first coupling layer in a portion of the first region. The second coupling layer may include a third hole overlapping the first hole and the second hole.

According to various embodiments of the present disclosure, the second hole and the third hole may have difference sizes to define a further step.

According to various embodiments of the present disclosure, a width of the third hole may be greater than a width of the second hole.

The display apparatus according to various embodiments of the present disclosure may further include a controller disposed on a printed circuit board. The second and third holes may overlap the controller.

According to various embodiments of the present disclosure, the controller may include a first controller and a second controller spaced apart from the first controller. The first hole may be disposed between the first controller and the second controller.

It will be apparent to those skilled in the art that various modifications and variations may be made in the present disclosure without departing from the scope of the disclosure. Thus, it is intended that the present disclosure covers the modifications and variations of this disclosure and their equivalents. The appended claims are not limited by the disclosure.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus, comprising:
a display panel including a first region, a second region overlapping the first region, and a third region between the first region and the second region;
a printed circuit board disposed in the first region and the second region; and
a controller disposed on the printed circuit board,
wherein the display panel is bent in the third region, and
wherein the printed circuit board includes a first hole.

2. The display apparatus of claim 1, further comprising:
a first coupling layer disposed on the printed circuit board in a portion of the first region.

3. The display apparatus of claim 2, wherein the first coupling layer includes a second hole.

4. The display apparatus of claim 3, wherein the second hole overlaps the first hole.

5. The display apparatus of claim 4, wherein the first hole has a first size and the second hole has a second size equal to the first size.

6. The display apparatus of claim 4, wherein the second size is greater than the first size to define a first step between the printed circuit board and the first coupling layer.

7. The display apparatus of claim 6, wherein the second hole covers the first hole.

8. The display apparatus of claim 7, further comprising:
a second coupling layer disposed under the first coupling layer in the portion of the first region, the second coupling layer including a third hole.

9. The display apparatus of claim 8, wherein the third hole has a third size greater than the second size and covers the second hole to define a second step between the first coupling layer and the second coupling layer.

10. The display apparatus of claim 6, wherein the second hole overlaps the controller.

11. A display apparatus, comprising:
a display panel including a first region, a second region overlapping the first region, and a third region between the first region and the second region;
a printed circuit board disposed in the first region and the second region; and
a controller disposed on the printed circuit board,
wherein the display panel is bent in the third region,
wherein the printed circuit board includes a first hole, and
wherein the controller includes a first controller and a second controller spaced apart from the first controller.

12. The display apparatus of claim 11, further comprising:
a first coupling layer disposed between the printed circuit board and the first region,
wherein the first coupling layer includes a pressure sensitive adhesive, and
wherein the first coupling layer includes a second hole that cooperates with the first hole to define a step.

13. The display apparatus of claim 11, further comprising:
a first coupling layer disposed between the printed circuit board and the first region; and
a plate layer under the first coupling layer in the first region.

14. The display apparatus of claim 11, wherein the first hole is disposed between the first controller and the second controller.

15. A display apparatus, comprising:
a display panel including a first region, a second region overlapping the first region, and a third region between the first region and the second region;
a printed circuit board disposed in the first region and the second region; and
a first coupling layer disposed in a portion of the first region and being under the printed circuit board,
wherein the printed circuit board includes a first hole,
wherein the first coupling layer includes a second hole,
wherein the first hole and the second hole overlap each other, and
wherein the first hole and the second hole have different sizes to define a step.

16. The display apparatus of claim 15, wherein a width of the second hole is greater than a width of the first hole.

17. The display apparatus of claim 16, further comprising:
a second coupling layer between the first coupling layer and the first region,
wherein the second coupling layer includes a third hole overlapping the first hole and the second hole.

18. The display apparatus of claim 17, wherein the second hole and the third hole have difference sizes to define a further step.

19. The display apparatus of claim 18, wherein a width of the third hole is greater than a width of the second hole.

20. The display apparatus of claim 17, further comprising:
a controller disposed on the printed circuit board, wherein the second hole and the third hole overlap the controller.

21. The display apparatus of claim 20, wherein the controller includes a first controller and a second controller spaced apart from the first controller, and
wherein the first hole is disposed between the first controller and the second controller.
